(19) United States
(12) Patent Application Publication
(10) Pub. No.: US 2013/0057776 A1
(43) Pub. Date: Mar. 7, 2013

(54) TELEVISION AND ELECTRONIC APPARATUS

(71) Applicants: Akifumi Yamaguchi, Kawasaki-shi (JP); Nobuto Fujiwara, Hamura-shi (JP); Hiroaki Itakura, Ome-shi (JP); Atsushi Tatemichi, Hamura-shi (JP); Issei Takahashi, Ome-shi (JP); Naoki Tani, Ome-shi (JP)

(72) Inventors: Akifumi Yamaguchi, Kawasaki-shi (JP); Nobuto Fujiwara, Hamura-shi (JP); Hiroaki Itakura, Ome-shi (JP); Atsushi Tatemichi, Hamura-shi (JP); Issei Takahashi, Ome-shi (JP); Naoki Tani, Ome-shi (JP)

(73) Assignee: KABUSHIKI KAISHA TOSHIBA, Tokyo (JP)

(21) Appl. No.: 13/468,884

(22) Filed: May 10, 2012

(30) Foreign Application Priority Data
Sep. 1, 2011 (JP) 2011-191126

(51) Int. Cl. H04N 5/64; H04N 5/50; H05K 7/20

(52) U.S. Cl. 348/731; 361/697; 348/E05.128; 348/E05.097

(57) ABSTRACT

According to one embodiment, a television includes: a display part; a tuner part; an electronic component; a casing including: a first wall provided with an opening part and configured to cover the electronic component; a second wall provided with a second opening part and configured to cover the electronic component; and a third wall provided with a third opening part over the first wall and the second wall; a stand part configured to support the casing; a fan accommodated within the casing; and a radiating member including regions facing the first opening part, the second opening part and the third opening part, and positioned between the fan and the third wall, wherein the second wall includes a recessed part and a projection projected toward the outside of the casing; and a part of the fan faces the recessed part from the inside of the casing.

### CROSS REFERENCE TO RELATED APPLICATION(S)

The application is based upon and claims the benefit of priority from Japanese Patent Application No. 2011-191126 filed on Sep. 1, 2011, the entire contents of which are incorporated herein by reference.

### BACKGROUND

1. Field

Embodiments of the present invention relates to a television and an electronic apparatus.

2. Description of the Related Art

In recent years, there have been popularized structures adapted to compulsorily enhance air permeability characteristic within an apparatus casing by using a fan unit followed by improvement in function and increase in heat of electronic apparatuses such as television, etc.

In these electronic apparatuses, improvement in cooling efficiency are required.

### BRIEF DESCRIPTION OF THE DRAWINGS

A general configuration that implements the various features of embodiments will be described with reference to the drawings. The drawings and the associated descriptions are provided to illustrate embodiments and not to limit the scope of the embodiments.

FIG. 1 is a front view showing a television which is an example of an electronic apparatus according to a first embodiment;

FIG. 2 is a cross sectional view taken along F2-F2 line showing the television shown in FIG. 1;

FIG. 3 is a perspective view showing a portable computer which is an example of an electronic apparatus according to a second embodiment;

FIG. 4 is a perspective view showing the internal part of the portable computer shown in FIG. 3 with a portion of a display cabinet and a first case of a casing being detached;

FIG. 5 is a top view showing a body part of the portable computer shown in FIG. 3;

FIG. 6 is a front view showing the body part of the portable computer shown in FIG. 5;

FIG. 7 is a cross sectional view taken along the F7-F7 line of the portable computer shown in FIG. 5;

FIG. 8 is a top view showing, in a perspective manner, the internal part of a first case of the casing in the body part of portable computer shown in FIG. 3;

FIG. 9 is a cross sectional view showing, in a cut state an a lateral direction, the body part by the height of a second duct of a speaker box in the body part shown in FIG. 8;

FIG. 10 is a perspective view showing a first case and a speaker box in the state where the second case of casing is detached in the body part of the portable computer shown in FIG. 3;

FIG. 11 is a perspective view showing a first case of the casing from the inside side (back side) thereof in the body part of the portable computer shown in FIG. 3;

FIG. 12 is a cross sectional view along a longitudinal direction of the portable computer shown in FIG. 5;

FIG. 13 is a perspective view showing a second case of the casing from the inside side (back side) thereof in the body part of the portable computer shown in FIG. 3;

FIG. 14 is a cross sectional view taken along the longitudinal direction of the body part of the portable computer shown in FIG. 5;

FIG. 15 is a diagram showing an exhaust part of the portable computer shown in FIG. 5;

FIG. 16 is a front view showing a tablet-type portable computer which is an example of an electronic apparatus according to a third embodiment; and

FIG. 17 is perspective view showing, from a backward direction, the tablet-type portable computer shown in FIG. 16.

### DETAILED DESCRIPTION

According to one embodiment, a television includes: a display part including a display screen on which a display image is displayed; a tuner part configured to receive a broadcasting wave; an electronic component provided separately from the display part; a casing including: a first wall provided with an opening part and configured to cover the electronic component from one direction; a second wall provided with a second opening part and configured to cover the electronic component from the other direction; and a third wall provided with a third opening part over the first wall and the second wall; a stand part configured to support the casing; a fan accommodated within the casing and configured to send wind toward at least the third opening part; and a radiating member including respectively regions facing the first opening part, the second opening part and the third opening part, and the radiating member being positioned between the fan and the third wall, wherein the second wall includes a recessed part and a projection projected toward the outside of the casing; and a part of the fan faces the recessed part from the inside of the casing.

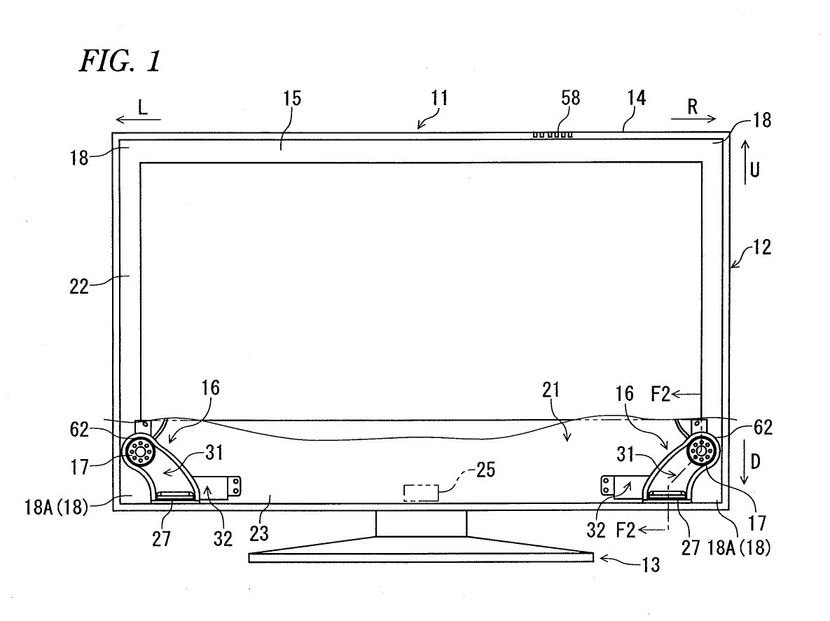

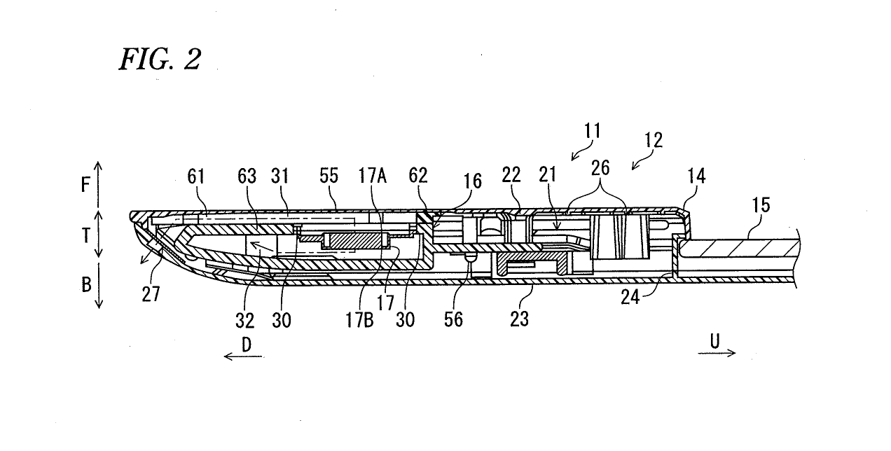

A preferred embodiment of a television which is an example of an electronic apparatus will now be described with reference to FIGS. 1 and 2. In the first embodiment, this side (i.e., user side) is defined as a forward direction F, depth side when viewed from user is defined as backward direction B, left side when viewed from user is defined left direction L, right side when viewed from user is defined as right direction R, an upper part when viewed from user is defined as upper direction U, and a lower part when viewed from user is defined as a lower direction D.

As shown in FIG. 1, a television 11 according to this embodiment is a thin type display apparatus having a rectangular outer appearance. As shown in FIG. 1, the television 11 includes, e.g., a body part 12, and a stand part (supporting part, pedestal, support part, leg part) for supporting the body part 12.

The body part 12 includes a casing 14 formed of, e.g., synthetic resin, etc. Moreover, the body part 12 includes, within a casing 14, a display panel 15 (display part, display module, display unit), a pair of speaker boxes (speaker parts, sound producing parts, boxes, supporting parts, housings) 16, two speakers 17 in total (a pair of speakers) respectively accommodated within the respective speaker boxes 16, a system board connected to the display panel 15 and adapted for supervisorial controlling the entirety of the television, a tuner board, and a power supply circuit board. It is to be noted that the display panel 15 is included of, e.g., a square liquid crystal panel, but may be included of any other kind of display panel, e.g. plasma display or organic EL panel, etc.

The casing 14 includes a plurality of corner parts (edge parts, corner part, end parts, edge parts, peripheral edge parts) 18, and a closed space provided on the side of the casing 14 and closed (substantially closed) (closed region space encompassed by wall, space in which poor permeability characteristic is maintained, region closed from the outside of the casing, region of which the entirety is encompassed by the internal wall of the casing and components, etc.) 21. The pair of speaker boxes 16 are accommodated within the closed space 21 of the casing 14. As shown in FIG. 2, the respective speakers 17 are accommodated within the speaker boxes 16 in a direction intersecting with the thickness direction T of the casing 14. At the plurality of corner parts 18, there are included a pair of corner parts 18A close to a lower direction D where the pair of speaker boxes 16 are provided.

The casing 14 includes a frame-shaped first case 22 (mask, first casing, first member, first wall, wall, face) for covering the front face of the display panel 15, and a second case 23 (cover, second casing, second member, second wall, wall, face) for covering the back face of the display panel 15. The internal face of the first case 22 and the internal face of the second case 23 are spaced so that components can be accommodated, and there are provided, between one face of the first case 22 and the other face of the second case 23, a peripheral wall (side wall, part ranging thereover, a portion of the first case 22 or the second case 23, wall standing on a peripheral wall of the first case 22 or the second case 23, partitioning part provided at the peripheral edge of the first case 22 or the second case 23, wall surrounding included components projected from the first case 22 or the second case 23).

Moreover, the first case 22 is a part to be mainly visually recognized from user, and the second case 23 is a part positioned on the side opposite to the first case 22 and difficult to see from user. The casing 14 includes a closed space 21 at a position close to the forward direction F therewithin. The periphery of the closed space 21 is prescribed by, e.g, the first case 22 and the second case 23 of the casing 14, and a projected part (projection, peripheral part, peripheral wall, wall, side part, face, region) 24 projected from the second casing 23. The projected part 24 is an example of a member for prescribing the periphery of the closed space 21, and is not limited to a projected part projected from the second casing 23, but may be projected from the first case 22 or may be detachable with respect thereto.

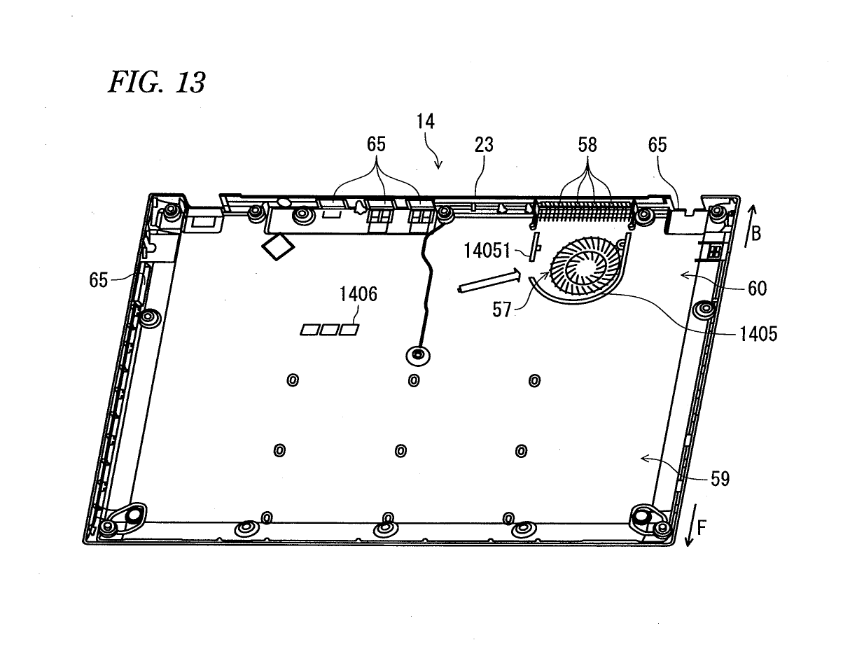

One face of the first casing 22, and the other face and the peripheral wall of the second casing 23 are respectively provided with exhaust parts 58 (opening parts, holes, air permeability parts, intake parts. These exhaust parts 58 are provided within a region (parts including both opposite walls and region ranging over the walls) which is channel shape in cross section from one face of the first case 22 to the other face of the second case 23. A practical configuration thereof will now be described later in conjunction with another embodiment with reference to FIG. 13. Moreover, the back face of the second case 23 is provided with a recessed part within which at least a portion of cooler (fan, motor) can be accommodated. The configuration of the recessed part will be described later in conjunction with another embodiment with reference to FIG. 13.

As shown in FIGS. 1 and 2, the first case 22 includes a part 55 facing the speaker box 16 (part opposite to the speaker box 16), and a second opening part (sound producing part, output part, sound producing region, output region) 25 formed, e.g., by collectively providing a plurality of very small penetration holes within a single region). The second opening part 25 is positioned between a pair of first opening parts 27 which will be later and is continuous to (communicates with) (facing) the closed space 21. At the internal face of the first case 22, a plurality of ribs (projected parts, reinforced parts, lattice parts, supporting parts, supports) 26 for reinforcement for reinforcing the first case 22 are provided in an array form like honeycomb-shape or lattice shape, etc. Since the configuration of the plurality of ribs 26 are similar to those in the second embodiment, the detailed description thereof will be given in the second embodiment.

The second case 23 includes a pair of first opening parts 27 provided in the vicinity of the respective speaker boxes 16 (i.e., in the vicinity of the respective corners 18). The first opening part 27 extends in a direction intersecting with the thickness direction T of the casing 14.

Each speaker box 16 includes a supporting part 30 for supporting the speaker 17, a first duct (guide part, communicating part, member surrounding a part from one face to the peripheral face, member extending toward the first opening part 27) 31 for guiding sound from the first face 17A of the speaker 17 to the first opening part 27, and a second duct (guide part, communicating part, member surrounding a part from one face to the peripheral part, member extending toward the closed space 21) 32 for guiding sound from the second face 17B on the side opposite to the first face 17A of the speaker 17 toward the closed space 21. Since the configurations of the respective speakers 17, the configurations of the respective boxes 16 and the structures of the peripheral structure of the boxes 16 are similar to those of the second embodiment, the detail thereof thereof will be described later in the second embodiment.

Subsequently, the operation of the speaker 16 of this embodiment will now be described. In this embodiment, sound outputted from the first face 17A of the speaker 17 is guided by the first duct 31, and is transmitted from the first opening part 27 toward the outside of the casing 14. In this instance, sound mainly guided by the first duct 31 and transmitted from the first opening part 27 is sound in a high frequency band and in intermediate band (e.g., more than several hundreds Hz) relatively having directivity. Sound from the second face 17B of the speaker 17 is guided by the second duct 32, and is outputted into the closed space 21 of the casing 14 so that it resonates within the closed space 21. Moreover, sounds outputted from the left and right speaker boxes 16 (second duct 32) are synthesized within the closed space 21 so that it is enhanced. The sound guided toward the closed space 21 is mainly sound in a low frequency band (e.g., less than several hundreds Hz). A greater part of the sound enhanced within the closed space is passed through a second opening part 25 provided at the first case 22, and is transmitted toward he outside of the casing 14 (is transmitted also from other penetration holes provided at the casing 14 toward the outside).

It is to be noted that there is employed, in this embodiment, such a configuration to transmit sound in the low frequency band toward the outside of the casing 14 through the second opening part 25, the closed space 21 may be placed in completely (substantially completely) closed state to vibrate the casing 14 itself to thereby to transmit sound toward the outside.

In accordance with the first embodiment, the television 11 includes: the casing 14 including a pair of corner parts 18A and the closed space 21; the pair of speaker boxes 16 accommodated within the closed space 21 in the vicinity of the respective corner parts 18, and the pair of speakers 17 accommodated in a direction intersecting with the thickness direction T of the casing 14 within the pair of speaker boxes 16, wherein the casing 14 includes a pair of first opening parts 27 provided in the vicinity of the respective speaker boxes 16, and the second opening part 25 positioned between the pair of first opening parts 27 and continuous to the closed space 21, and each speaker box 16 includes the first duct 31 for guiding sound from the first face 17 A of each speaker 17 toward each first opening part 27, and the second duct 32 for guiding sound from the second face 17B on the side opposite to the first face 17A of each speaker 17 toward the closed space 21.

In accordance with this configuration, since the speaker 17 is provided in a direction intersecting with the thickness direction T of the casing 14, it is possible to provide speaker 17 having large size within the casing 14. Since it is desirable for outputting good sound to use circular speaker 17 having a suitable size, the above-described configuration can realize high tone quality without increasing the thickness size of the casing 14.

Moreover, in accordance with the above-described configuration, it is possible to output sound from the first face 17A of the speaker 17 toward the outside of the casing 14 via the first duct 31 as it is. Moreover, it is possible to guide sound from the second face 17B of the speaker 17 into the closed space 21 via the second duct 32 to resonate sound mainly in the low frequency band within the closed space 21. Thus, sounds in the low frequency band outputted from the second duct 32 of each speaker box 16 are synthesized within the closed space 21 so that it is enhanced, whereby such enhanced sound is transmitted toward the outside of the casing 14 through the second opening part 25. In this way, since there is employed in this embodiment such a scheme such that sound is outputted by way of different two paths, it is possible to produce deep sound to realize high tone quality.

Since the detail of other respective components are similar to the second embodiment, the following second embodiment will now be described.

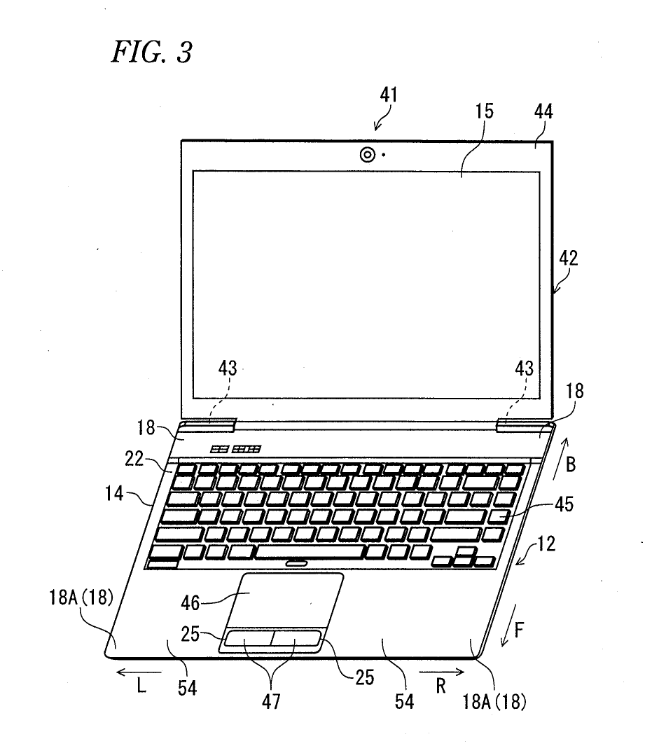

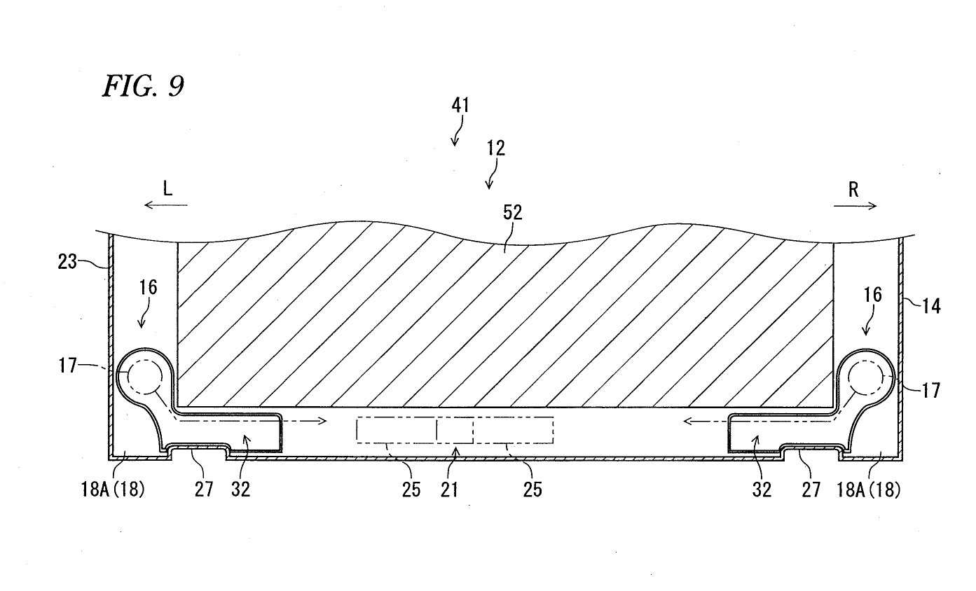

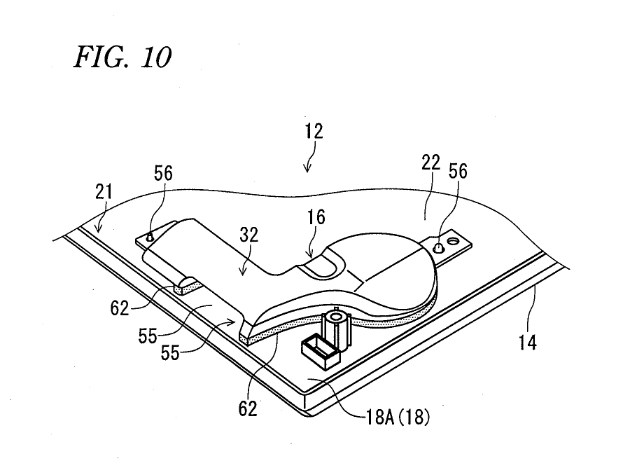

Subsequently, the second embodiment of the electronic apparatus will now be described with reference to FIGS. 3 to 11. A portable computer 41 which is an example of the electronic apparatus of the second embodiment has an outer appearance different from the television 11 of the first embodiment, but the structure at the periphery of the body part 12 is approximately similar to that of the first embodiment. Moreover, in the following the embodiments, this side (i.e., user side) is defined as forward direction F, the depth side when viewed from user is defined as backward direction B, the left side when viewed from user is defined as left direction L, the right side when viewed from user is defined as defined as right direction R, upper part when viewed from user is defined as upper direction U, and the lower part when viewed from user is defined as lower direction D.

As shown in FIG. 3, the portable computer 41 is so-called notebook-type personal computer. The portable computer 41 includes a body part (first part, supporting part for displaying display part) 12, a display part (display part, second part) 42 which is covered with respect to the body part 12 (display is in closed•covered state), and which can be stood with respect to the body part 12 (in the state where (display is in a state along a direction intersecting with the display part 12•in an exposed state), and a hinge part (joining part, connecting part, rotating part) 43 provided between the body part 12 and the display part 42. The display part 42 includes a display panel 15 (display part, display module, display unit, component), and a display cabinet 44 (casing, covering part, wall, face) for covering the periphery of the display panel 15.

The display panel 15 is, in this embodiment, included of, e.g, a square (substantially square, rectangular) plate-shaped liquid crystal panel, but may be included of, e.g., any other kind of display such as plasma display panel, or organic EL panel, etc.

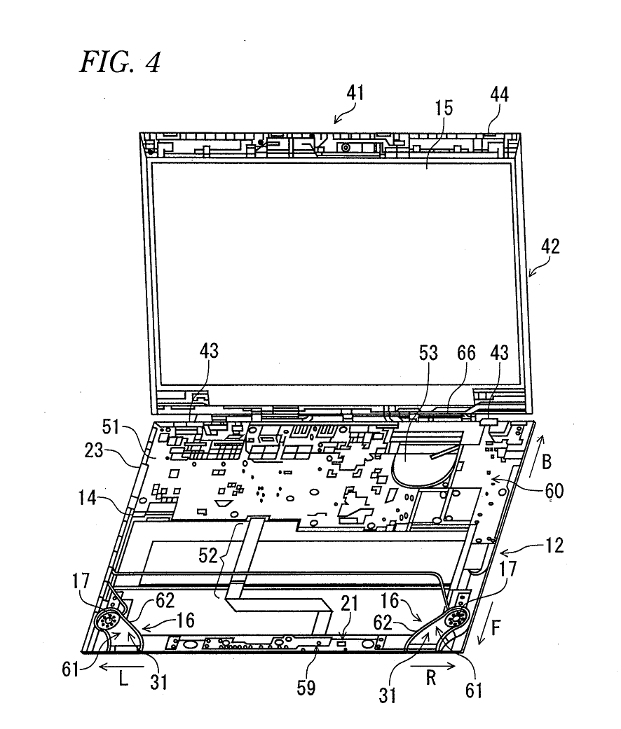

The body part 12 includes a casing (casing component member, assembly component, surrounding part) 14 formed by metal, e.g., magnesium alloy, a keyboard (input part, input receiving part, receiving part, operating part, operation region, interface part, input module, unit, component) 45 attached at the casing 14 and a touch pad (input part, input receiving part, receiving part, operating part, operation region, interface part, input module, unit, component, face, region where touch sensor functions) 46, and a touch pad button 47 (input part, input receiving part, receiving part, operating part, operation region, interface part, input module, unit, component, button) provided at the casing 14 in the vicinity of the touch pad 46. As shown in FIG. 4, the body part 12 includes, within the casing 14, a printed circuit board (board, electronic component, component, module) 51, a battery unit (battery, power supply part, unit, charger, component, module) 52, a fan unit (cooler, fan, heat radiating part) 53 for cooling components on the printed circuit board 51, a pair of speaker boxes (boxes, supporting parts, housings) 16, and two speakers 17 (a pair of speakers, output parts) in total respectively within the speaker boxes 16. The printed circuit board 51 serves to supervisorily control the entirety of the portable computer 41. The battery unit 52 is provided at a position close to the forward direction F within the casing 14 (position close to touch pad•touch pad button•palm rest side, position close to the side opposite to the display hinge, position apart from the fan unit, position apart from the air permeability part•connector opening part of the casing). The fan unit 53 is provided at a position close to the backward direction B within the casing 14 (at position close to the side opposite to the touch pad•touch pad button•palm rest side, position close to the display•hinge, position apart from the battery unit, within a space with which the air permeability part of the casing•connector opening part communicate).

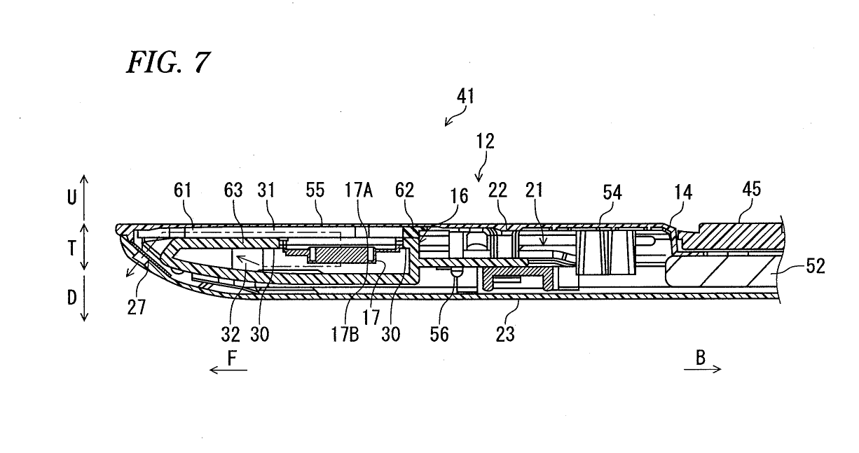

As shown in FIG. 7, the casing 14 includes a plurality of corner parts (corner portions, corner parts, end parts, edge parts, peripheral parts) 18, a first case (mask, first casing, first member) 22 provided at a position (upper side) which is visually recognized by user, and a second case (cover, second casing, second member, bottom) 23 provided on the side opposite to the first case 22 (lower side) and provided adjacently to (combined with) the first case 22. At a plurality of corner parts, there are provided a pair of corner parts 18A close to the front direction F where a pair of speaker boxes 16 are provided.

The casing 14 includes closed space 21 at a position close to the forward direction F therewithin. The closed space 21 is provided at a position of the inside (front end part of the casing 14, end part or edge part on the side opposite to the end part where hinge is provided) of the palm rest part (wall, face, region on the side opposite to the hinged display relative to the keyboard) 54. The periphery of the closed space 21 is prescribed (encompassed) by, e.g., the first case 22 and the second case 23 of the casing 14 and the battery unit 52. The battery unit 52 is an example of a member for prescribing the periphery of the closed space 21, but may be component or structure including part, wall, face and region having a shape ranging over the first case 22 and the second case 23 within the casing 14, and may be, e.g., a standing wall projected from the inside of the casing 14 or a wall constituted by closely arranging a plurality of components, etc. The pair of speaker boxes 16 are accommodated within this closed space 21.

The respective speakers 17 are accommodated in a direction intersecting with the width direction T of the casing 14 within the speaker box 16. The speaker 17 has a size, e.g., inner diameter of 16 mm to 20 mm, and is circular.

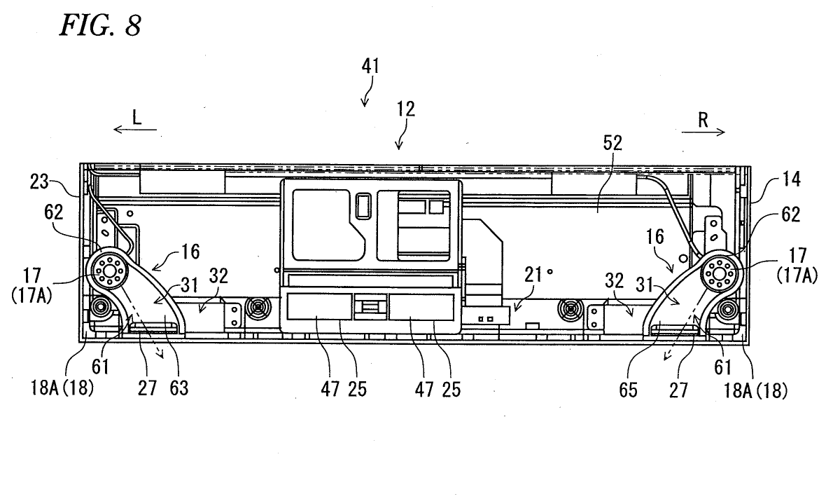

The first case 22 includes a keyboard 45 attached at substantially the central part (position encompassed by the peripheral part), and includes palm rest part 54, touch pad 46, and touch pad button 4 7 provided at a position close to the forward direction F relative to the keyboard 45. The first case 22 includes the second opening part 25 continuous to the closed space 21, and touch pad button 47 on the inside of the second opening part 25. As shown in FIG. 8, the second opening part 25 is positioned between a pair of first opening parts 27 which will be later.

The first case 22 includes a part (face, internal face, wall, region) 55 facing to the speaker box 16 (part opposite to the speaker box 16), and a plurality of ribs (projected parts, reinforcement parts, lattice parts, supporting parts, supports) 26 for reinforcement projected toward the inside (closed space 21). The plurality of ribs 26 take honeycomb shape (hexagonal shape), and are provided at a position mainly corresponding to the palm rest part 54. It should be noted that although each rib 26 is designed as honeycomb shape, even if there is employed a configuration capable of ensuring rigidity•torsional rigidity•deformation suppressing function of the casing 14 to a certain degree, there may be employed, e.g., a configuration in which ribs may be arranged in a lattice form or in any other form.

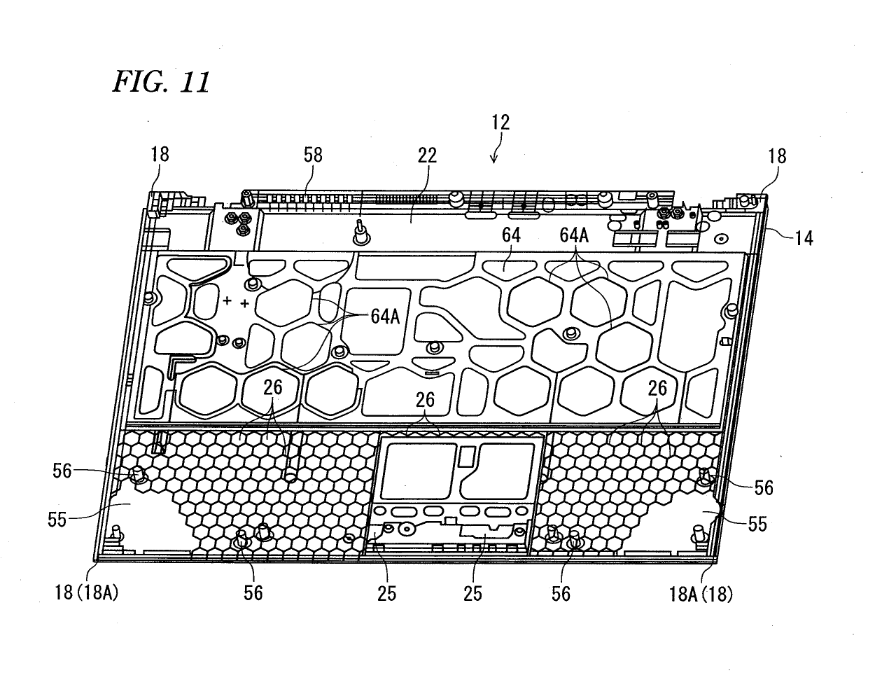

As shown in FIG. 11, a plurality of ribs 26 are provided at a position out of the part 55, and are not provided at the part 55 facing the speaker box 16. Namely, the ribs 26 are projected in a manner to avoid the part 55. Moreover, the first case 22 includes a pair of positioning pins (projected parts, positioning parts, fixing parts, supporting parts) 56 for performing positioning of the speaker box 16.

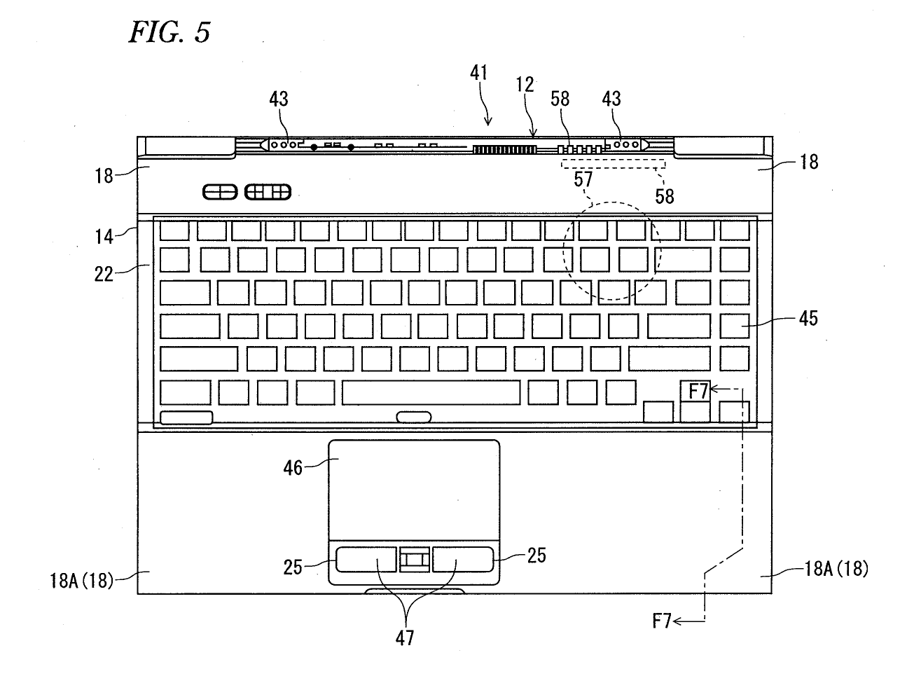

The second case 23 includes, as a pair, first opening parts 27 in the vicinity of the pair of corner parts 18A and in the vicinity of the pair of speaker boxes 16. The first opening part 27 is provided at the second case 23 which is difficult to see from user, i.e., is provided in the forward direction F which is the so-called user side. The first opening part 27 is provided at a curved part (part where curved design curve is provided) close to the forward direction F of the second case 23 (see FIG. 7). The first opening part 27 extends in a direction intersecting with the thickness direction T of the casing 14. Further, the second case 23 includes an intake part 57 for fan unit and an exhaust part 58 for fan unit at a position close to the backward direction B of the casing 14 (see FIG. 5).

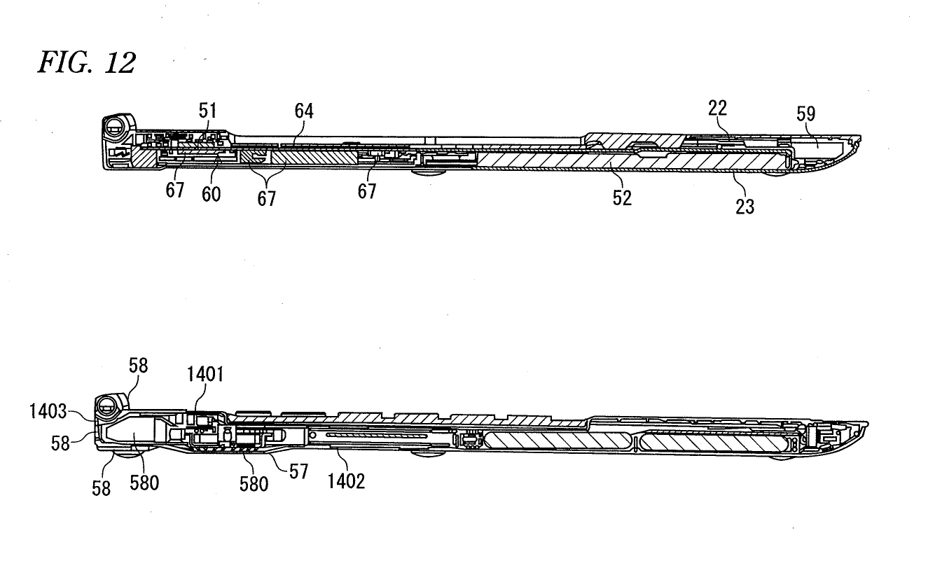

As shown in FIG. 12, the battery unit 52 has a length direction along a length direction of the casing (along a direction where a pair of speakers are arranged). Moreover, the battery unit 52 has a height sufficient to close the closed space 21 (height ranging over the internal face opposite to the casing 14 in the thickness direction thereof, thickness equal•substantially equal to the inside of the casing 14, height capable of shielding•substantially shielding air permeability characteristic within the casing), and serves to partition a first region 59 where the speaker box 16 is provided (speaker region, space within which sound is reflected, part at the front part of the casing, space where poor air permeability characteristic is maintained with respect to the outside of the casing), and a second region 60 (cooling region, space within which electronic components are gathered, space within which good air permeability characteristic from the outside can be maintained) in which there are arranged printed circuit board 51 and components (electronic components, heating elements), fan unit (fan, fan case, motor, fan blade) 53, and cooling fins (radiating part, heating part) 66 toward which wind from the fan unit 53 is caused to flow. Thus, the battery unit 52 can exhibit sound shielding effect so that there is no possibility that noise from the fan unit 53, etc. (sound when wind flows within the case, wind noise of the fan blade, vibration•operating sound of motor, operation sound of electronic component) may be mixed into sound in a low frequency band which will be later within the closed space 21 (first region 59).

As shown in FIGS. 4 and 13, the intake part (extruded part, projected part, convex part, projection, fan accommodating part, motor accommodating part, swollen part) 57, exhaust part 58, an opening part 65 for connector are concentrated onto a second region 60 close to the backward part B of the casing 14 (are positioned in a manner close thereto). Moreover, since the first region 59 and the second region 60 are partitioned by the battery unit 52, even if any air permeability holes are provided at the first region 59, there is no possibility that air of the second region 60 may flow into the first region 59 (air flow can be suppressed).

As shown in FIGS. 11 and 12, the first case 22 includes a keyboard support (supporting part, support part, plate part, support face, wall) 64 for supporting the keyboard 45. The keyboard support 64 includes a plurality of hexagonal (honeycomb)-shaped holes 64A. As shown in FIG. 12, since one face of the printed circuit board 51 is in closely in contact (substantially closely in contact, in contact) with the keyboard support 64 (with an insulator (not shown) being put therebetween), it is prevented that sound from the fan unit 53, etc. may leak out from the hole 64A toward the outside of the casing 14.

Since such a configuration is realized, there is employed, in this embodiment, such components (components having a shape projected from the surface such as surface mounting components, etc.) provided on one surface of the printed circuit board 51 are arranged in a manner in corresponding with the internal edge shape of the hole 64A so as to avoid a face opposite to a beam shaped part encompassed by the holes 64A.

As shown in FIG. 12, a plurality of components 67 having high height dimension are concentrically provided on the other face on the side opposite to the one face of the printed circuit board 51. For this reason, in this embodiment, one face of the printed circuit board 51 can be arranged in such a manner that it closely comes into contract with the keyboard support 64 so that use efficiency of the space within the casing 14 can be considerably improved.

As shown in FIG. 4, etc., the length direction of the printed circuit board (board) 51 is along the length direction (in left and right directions) of the casing 14. For this reason, wind flows along the length direction of the casing 14 within the second region 60 partitioned by the battery unit 52. For this reason, it can be said that the shape of the printed circuit board (board) 51 is along wind flowing direction. Since large sized components (components having mounting height to some degree) particularly having high calorific value are concentrated onto the other face where wind flows in such a manner that it is transmitted on the surface thereof, these components can be collectively radiated.

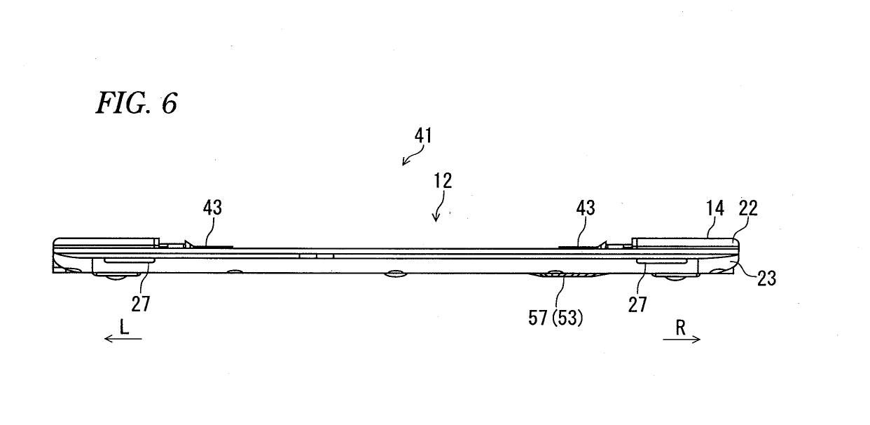

As shown in FIGS. 6 and 13, etc., a portion (motor) of the fan unit 53 and the bottom wall of the casing 14 (second case 23) corresponding thereto are projected downwardly relative to the bottom wall of any other part. Moreover, a plurality of air permeability holes (opening parts) are provided at a part projected downwardly relative to the bottom wall. For this reason, noise and vibration from the fan unit 53 are difficult to be transmitted into the casing 14.

Moreover, rubber legs for supporting the casing 14 are positioned directly beyond connectors having high height (RGB connectors and LAN connectors). By this configuration, it becomes possible to incline the casing 14 forwardly. If the casing 14 takes an attitude inclined forwardly, it can become difficult to propagate sound within the second region 60 by the user side (the keyboard and/or the printed circuit board which are sound shielding object positioned between the casing 14 and the second region 60 can be directed to user).

As shown in FIG. 13, the exhaust part 58 is provided at the side wall of the backward direction B of the casing 14 to cause wind from the fan unit 53 to be discharged toward the outside of the casing 14 in the backward direction B. For this reason, it can be said that the position of the exhaust part 58 is positioned in a direction opposite to the first opening part 27 and the second opening part 25 shown in FIGS. 3 and 5. Accordingly, exhaust sound produced from the exhaust part 58 would be outputted in a direction opposite to sound from the speaker 17. Thus, there is no possibility that such a phenomenon may exert bad influence on sound effect exhibited by the speaker box 16.

Each speaker box 16 is provided at the front part F of the casing 14. Each speaker box 16 is formed in such a manner that a single speaker 17 can be accommodated therewithin by, e.g., synthetic resin. Each speaker box 16 is subjected to positioning through positioning pin 56 with respect to the first case 22 of the casing 14, and is fixed by means of, e.g., screws (fixing metal fittings, fitting parts, fastening members, fixing parts), etc. As shown in FIG. 7, the speaker box 16 includes a supporting part 30 for supporting the speaker 17, a first duct (guide part, communicating part, member encompassing a part from one face to the peripheral face, member extending toward the first opening part 27, member, wall, surrounding part) 31 for guiding sound from the first face 17A (front face) of the speaker 17 toward the first opening part 27 (guide part, communicating p, and second duct (guide part, communicating part, member encompassing a part from one face to the peripheral face, member extending toward the second opening part 25, member, wall, surrounding part) 32 for guiding sound from the second face 17B (back face) of the speaker 17 toward the closed space 21 and the second opening part 25 continuous thereto.

One wall (a part) of the first duct 31 is included of part 55 facing speaker box 16 of the first case 22 of the casing 14. For this reason, more precisely, the speaker box 16 includes a groove part (opening part, recessed part, projected part, standing wall part, wall part) 61 constituting the other wall (the other part) of the first duct 31. The groove part 61 includes an elastic member (member having low rigidity, flexible member, deformable•displaceable member) 62 for prescribing the peripheral edge thereof, and a wall part (face part) 63 constituting (doubling as) a portion of the second duct 32. The elastic member 62 is bonded to the wall part 63. The elastic member 62 is included of, e.g., sponge, but may be any other kind of elastic body such as rubber, etc. The speaker box 16 is provided adjacently to the part 55 of the first case 22 through the elastic member 62. The second duct 32 is formed tubular.

Subsequently, the operation of the speaker box 16 of this embodiment will now be described with reference to FIGS. 7 to 9. In this embodiment, the speaker 17 produces sound toward the internal face of the casing 14 (region encompassed by the ribs 26). Namely, the sound producing face faces the internal face of the first case 22. Sound outputted from the first face 17A of the speaker 17 is guided by the first duct 31, and is outputted from the first opening part 27 toward the outside of the casing 14. In this instance, the sound mainly guided by the first duct 31 and outputted from the first opening part 27 is sound in a high frequency band and in an intermediate frequency band relatively having directivity to a certain degree (e.g., more than several hundreds Hz). Sound outputted from the second face 17B of the speaker 17 is guided by the second duct 32, and is outputted into the closed space 21 of the casing 14 so that it resonates within the closed space 21. Further, sounds outputted from the left and right speaker boxes 16 (the second duct 32) are synthesized within the closed space 21 so that the synthesized sound is enhanced. Sound guided into this closed space 21 is sound in a low frequency band mainly having directivity to a little degree (e.g., less than several hundreds Hz). A large part of the sound enhanced within the closed space 21 is passed through the second opening part 25 provided at the first case 22, and is transmitted toward the outside of the casing 14 (is transmitted from any other penetration holes provided at the casing 14 toward the outside).

It should be noted that although there is employed, in this embodiment, such a scheme to transmit sound in the low frequency band toward the outside of the casing 14 through the second opening part 25, there may be employed such a scheme to allow the closed space 21 to be placed in completely closed state to vibrate the casing 14 itself to thereby transmit sound toward the outside.

In accordance with second embodiment, the portable computer 41 includes a casing 14 including a pair of corner parts 18A, a pair of speaker boxes 16 accommodated within the casing 14 in the vicinity of respective corner parts 18, and a pair of speakers 17 accommodated in a direction intersecting with the thickness direction T of the casing 14 within the pair of speaker boxes 16, wherein the casing 14 includes a pair of first opening parts 27 provided in the vicinity of the respective speaker boxes 16, and a second opening part 25 positioned between the pair of first opening parts 27, and the each speaker box 16 includes first duct 31 for guiding sound from the speakers 17 toward the respective first opening part 27, and second duct 32 for guiding sounds from the respective speakers 17 toward the second opening part 25.

In accordance with this configuration, since each speaker 17 is provided in the direction intersecting with the thickness direction T of the casing 14, it is possible to provide speaker 17 having large size within the casing 14. Since it is necessary for outputting good sound to use a circular speaker having a size to some degree, the above-mentioned configuration can realize high tone quality without increasing the thickness dimension of the casing 14.

Moreover, in accordance with the above-mentioned configuration, it is possible to transmit sound from the speaker 17 as it is toward the outside of the casing 14 via the first duct 31. Further, sound from the speaker 17 is guided into the closed space 21 via the second duct 32, thus to have ability to resonate sound mainly in the low frequency band within the closed space 21. The sounds in the low frequency band produced from the second duct 32 of respective speaker boxes 16 are synthesized within the closed space 21 so that the synthesized sound thus obtained is enhanced. The enhanced sound is transmitted to the outside of the casing 14 through the second opening part 25. As described above, in this embodiment, since sounds are transmitted toward the outside of the casing 14 by way of different two paths, it is possible to produce deep sound to realize high tone quality.

Moreover, the casing 14 includes part 55 facing the speaker box 16, wherein the part 55 forms a single wall of the first duct 31, and each speaker box 16 includes a groove part 61 constituting the other wall of the first duct 31. In accordance with this configuration, since the casing 14 is permitted to double as one wall part of the first duct 31, it is possible to reduce the thickness dimension of the speaker box 16 as compared to the case where both the first duct 31 and the second duct 32 are provided within the speaker box 16. Thus, it is possible to realize further thin structure of the casing 14.

Further, the groove part 61 includes an elastic member 62 prescribing the peripheral edge thereof and in contract with the part 55. In accordance with this configuration, it is possible to absorb, by the elastic member 62, vibration of the speaker box 16 produced when sound is produced. Thus, there is no possibility that vibration produced at the speaker box 16 may be transmitted to the casing 14 as it is to prevent that any vibration takes place in the casing 14 to have ability to prevent that feeling in quality of the portable computer 41 is lowered, (i.e., the portable computer 41 is permitted to have high-grade feeling.).

The portable computer 41 includes a member provided within the casing 14 and for prescribing the periphery of the closed space 21. In accordance with this configuration, it is possible to prevent that sound may leak from the closed space 21 to enhance sound in the low frequency band (is caused to resonate) within the closed space 21 thus to have ability to realize high tone quality.

Moreover, the casing 14 includes first case 22 visually recognized by user, and second case 23 on the side opposite to the first case 22, wherein the first opening part 27 is provided at the second case 23. In accordance with this configuration, the first opening part 27 is permitted to be difficult to see from user thus to have ability to improve feeling in the quality of the portable computer 41.

The first opening part 27 extends in a direction intersecting with thickness direction of the casing 14. In recent years, since realization of thin structure of the casing 14 of the portable computer 41 is considerably developed, the first opening part 27 is permitted to be difficult to see from user similarly also by this configuration. Thus, it is possible to improve feeling in quality of the portable computer 41.

Further, the casing 14 includes ribs 26 projected toward the closed space 21 at a position out of the part. In accordance with this configuration, it is possible to prevent that transmission of sound within the first duct 31 is hindered by the ribs 26 thus to have ability to realize a scheduled sound effect. In addition, it is possible to prevent that the ribs 26 and the speaker boxes 16 interfere with each other thus to have ability to contribute to realization of thin structure of the casing 14.

Further, the closed space 21 is provided on the inside of the palm rest part 54 provided at the casing 14. In accordance with this configuration, the closed space within the palm rest part 54 can be effectively utilized as a portion for allowing sound to resonate. Thus, it is possible to realize high tone quality without producing special increase in the space. Furthermore, since the first opening part 27 is provided on the user side of the second case 23, sound transmitted from the first opening part 27 is efficiently transmitted to user. Thus, it is possible to realize high tone quality. In addition, there is no possibility that the first opening part 27 may be clogged by hand of user.

Subsequently, the third embodiment of the electronic apparatus will be described with reference to FIGS. 12 to 15.

In this embodiment, a rectangular casing 14 is partitioned into three faces (three walls) of a side wall 1403 of the rectangular casing 14, and upper and lower walls 1401, 1402 in the vicinity of the side wall 1403, and exhaust parts 58 are respectively provided at those walls. Each exhaust part 58 serves to evacuate wind from the fan toward the outside of the casing 14. In this embodiment, evacuation is performed from three directions so that evacuating efficiency can be improved.

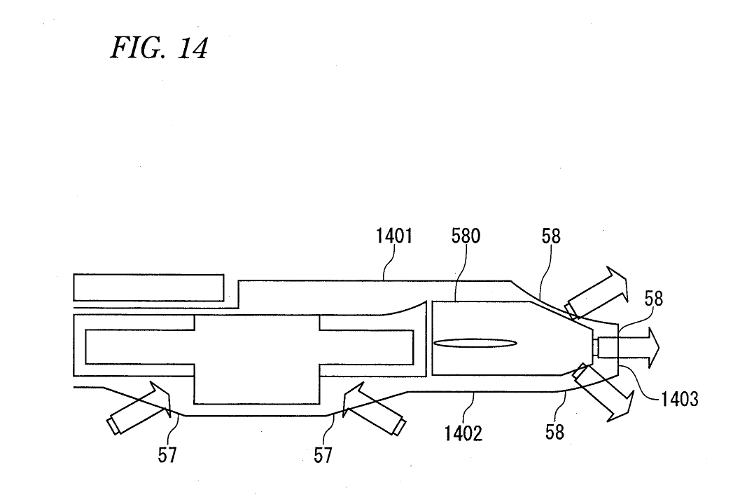

Moreover, in this embodiment, a part in the vicinity of the intake part 57 provided at the lower wall 1402 has a shape swollen toward the outside of the casing 14. The intake part 57 is provided on a swollen slanting face 1404. The cross section in the vicinity of the intake part 57 has a pedestal shape in cross section as shown in FIG. 14. Employment of such a configuration can increase intake region (flow path) until to intake holes of the fun.

Further, the intake part 57 is adapted so that the lower end (end, edge) of the motor is inserted into the swollen part thereof. By employing such a configuration, it is possible to suppress that the rotation function of the fan (force required for rotating fan blade) is lowered while thinning the entire thickness of the fan.

The exhaust part 58 provided at the lower wall 1402 is opened within a region where design curve (curved part) of the second case is provided. By employing such a configuration, air from the lower wall 402 flows without obstruction by top plate of desk, etc. Each exhaust part 58 provided at upper wall 1401 is opened within a region where the design curve (curved part) of the first case is provided, which avoids the hinge axis. By employing such a configuration, each exhaust part 58 provided at the upper wall 1401 is not conspicuous when viewed from user as shown in FIG. 3. Moreover, in this embodiment, design is made such that the shape of fins 580 are in correspondence with the curved part of upper and lower walls. In concrete terms, each fin 580 has a shape like rhombic shape in which the chip end thereof is narrow in a manner in correspondence with the curved part.

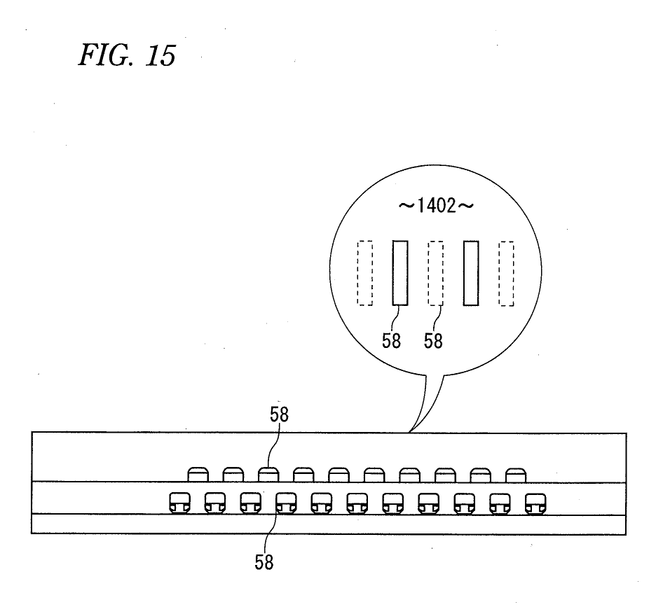

Moreover, as shown in FIG. 15, exhaust parts 58 provided at the upper and lower walls are respectively provided at positions intersecting with each other (positions of which centers are eccentric to each other, position out of positions overlapping with each other as far as possible). It is desirable that air from the fan uniformly flows along the length direction of the fan opening part (air densities of the flow path are substantially uniform). There are instances where the exhaust part provided at the electronic apparatus casing is adapted so that such a beam intersecting with the length direction of the fan opening part is provided for the reason such as removal of dust and/or rubbish from viewpoint of safety, etc. However, flow of air is changed as matter of course within the region where the beam exists and the region where no beam exists (because the beam serves wind preventing wall within the region where the beam exists). In the configuration of this embodiment, the position of the exhaust part, i.e., the position of the beam is displaced so that air density is distributed. This contributes to uniformity.

Moreover, for example, in the case where the directivity of air flow of the fan is high, air flow is mainly evacuated from the exhaust part 58 of the side wall 1403 positioned on the front face of the fan. In this case, there are instances where exhaust parts 58 provided at the upper and lower walls respectively function as intake parts, but the exhaust parts 58 provided at the upper and lower walls are respectively provided at positions intersecting with each other so that there is no possibility that air flows flowing into from the opening part may collide with each other.

Moreover, in the configuration of this embodiment, ribs (projected parts) 1405 are provided in a manner to surround the periphery of the slanting part 1404. It is possible to ensure a distance between the fan and the lower wall 1402 by the ribs 1405, and the ribs 1405 serve as wind preventing wall to suppress that warm air within the casing 14 circulates toward the fan. Moreover, cutting parts 14051 (region where ribs are simply provided so that there heights are low or are eliminated) are provided at a portion of the ribs 1405. This region serves to allow air from any other intake holes 1406 bored at the lower wall 1404 to pass through the fan.

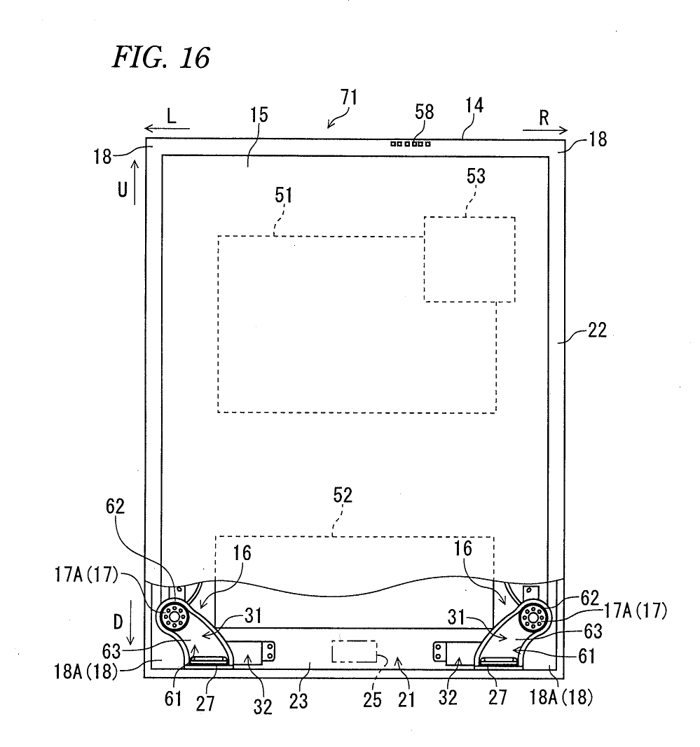

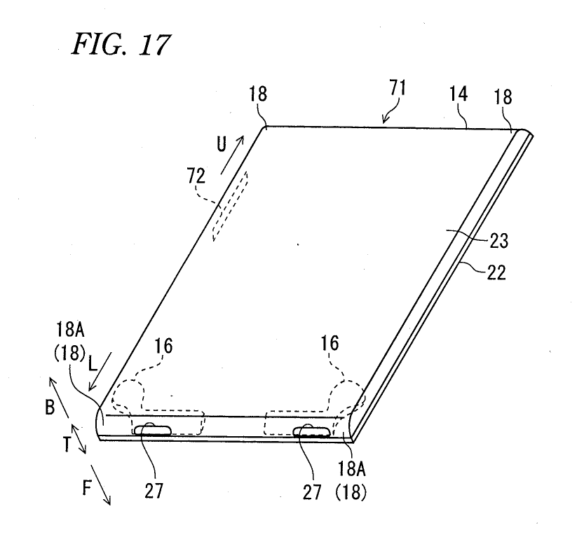

Subsequently, the third embodiment of the electronic apparatus will be described with reference to FIGS. 16 and 17. A tablet-type portable computer 71 which is an example of the electronic apparatus of the third embodiment has an outer appearance different from that of the structure of the second embodiment, but other components thereof are common to those of the second embodiment. For this reason, different components will be mainly described, and common reference numerals are respectively attached to common parts and their description will be omitted. Moreover, in the following embodiment, this side (i.e., user side) is defined as the forward direction F, the depth side when viewed from user is defined as the backward direction B, the left side when viewed from user is defined as the left direction, the right side when viewed from user is defined as the right direction, the upper part when viewed from user is defined as the upper direction, and the lower part when viewed from user is defined as the lower direction.

The tablet-type portable computer 71 includes a casing 14 formed by metal, e.g., magnesium alloy, and a touch panel type display panel 15 provided within the casing 14 in such a manner that a portion thereof is exposed to the outside. As shown in FIG. 16, the tablet-type portable computer 71 includes, within the casing 14, a printed circuit board 51, battery unit 52, fan unit 53, a pair of speaker boxes 16, and a pair of speakers 17. The printed circuit board 51 serves to supervisorily control the entirety of the portable computer 41. User touches finger, etc. with respect to the display panel 15 of the touch panel type, thereby making it possible to perform a desired operation with respect to the tablet-type portable computer 71.

As shown in FIG. 17, the casing 14 includes a plurality of corner parts 18, a first case 22 provided at a position (upper side) which is visually recognized by user, and a second case 23 provided on the side opposite to the first case 22 (lower side) and provided adjacently to the first case 22. At a plurality of corner parts 18, there are included a pair of corner parts 18A close to the lower direction D where the pair of speaker boxes 16 are provided. The casing 14 includes therewithin closed space 21 at a position close to the lower direction D. The periphery of this closed space 21 is prescribed by, e.g., the first case 22 and the second case 23 of the casing 14 and the battery unit 52. The battery unit 52 is an example of a member for prescribing the periphery of the closed space 21. A pair of speaker boxes 16 are accommodated within the closed space 21.

Similarly to the above-described two embodiments, also in the electronic apparatus of the third embodiment, exhaust parts 58 (opening parts, holes, air permeability parts, intake parts) are respectively provided at one face of the first case 22, and the other face and the peripheral wall of the second 23. These exhaust parts 58 are provided within a region which is channel shaped in cross section from one face of the first case 22 toward the other face of the second case 23 (a part including opposite both walls and a region ranging over the walls). Since the practical configuration is the same as the configuration which has been described with reference to FIG. 13, it is omitted. Moreover, at the back face of the second case 23, there is provided a recessed part within which at least a portion of cooler (fan, motor) can be accommodated. Since the configuration of the recessed part is also the same as the configuration which has been described with reference to FIG. 13, it is omitted.

The first case 22 includes a part 55 facing the speaker box 16, a second opening part 25 formed by collectively providing, e.g., a plurality of very small penetration holes within a single region, and a plurality of ribs 26 for reinforcement projected toward the inside (closed space 21). The second part 25 is positioned between a pair of first opening parts 27 which will be later, and are continuous to the closed space 21. The plurality of ribs 26 are provided on the internal face of the first case 22, and are formed to be honeycomb-shaped (hexagonal). Moreover, the plurality of ribs 26 are provided at a position out of the part 55, and are not provided at the part 55 facing the speaker box 16 similarly to the second embodiment.

The second case 23 includes a pair of first opening parts 27 in the vicinity of the pair of corner parts 18A, and in the vicinity of the pair of speakers 16. Each first opening part 27 is provided at the second case 23 which is difficult to see from user, and is provided in the downward direction D serving as the user side when used by hand. The first opening part 27 extends in a direction intersecting with the thickness direction T of the casing 14. Further, the second case 23 includes an intake•exhaust part 72 for the fan unit 53 at a position close to the upper direction U of the casing 14 (see FIG. 17).

The respective speaker boxes 16 are formed in a manner to accommodate a single speaker 17 therewithin by, e.g., synthetic resin. Each speaker box 16 includes a supporting part 30 for supporting the speaker 17, a first duct 31 for guiding sound from the first face 17A (front face) of the speaker 17 toward the first opening part 27, and a second duct 32 for guiding sound from the second face 17B (back face) of the speaker 17 toward the closed space 21 and the second opening part 25 continuous thereto.

A portion of the first duct 31 is included of the part 55 facing the speaker box 16 of the first case 22 of the first casing 14. For this reason, more precisely, the speaker box 16 includes a groove part 61 constituting any other part of the first duct 31. The groove part 61 includes an elastic member 62 for prescribing the peripheral edge thereof, and a wall part 63 constituting (doubling as) a portion of the second duct 32. The elastic member 62 is bonded to the wall part 63. The elastic member 62 is included of, e.g., sponge, but may be included of any other elastic member such as rubber, etc. The second duct 32 is formed tubular.

The operation of the speaker box 16 of this embodiment is similar to that of the second embodiment. It is to be noted that although sound in the low frequency band is transmitted toward the outside of the casing 14 through the second opening part 25 in this embodiment, the closed space 21 may be in a completely closed state to vibrate the casing 14 itself to thereby transmit sound toward the outside.

In accordance with the third embodiment, the portable computer 41 includes a casing 14 including a pair of corner parts 18A, a pair of speaker boxes 76 accommodated within the casing 14 in vicinity of the respective corner parts 18, and a pair of speakers 17 accommodated in a direction intersecting with the thickness direction T of the casing 14 within the pair of speaker boxes 16 wherein the casing 14 includes a pair of first opening parts 27 provided in the vicinity of the respective speaker boxes 16, and a second opening part 25 positioned between the pair of first opening parts 27; and the respective speaker boxes 16 includes a first duct 31 for guiding sound from the respective speakers 17 toward the respective first opening parts 27, and a second duct 32 for guiding sound from the respective speakers 17 toward the second opening part 25.

In accordance with this configuration, since the speaker 17 is provided in a direction intersecting with the thickness direction T of the casing 14, it is possible to provide speaker 17 having large inner diameter within the casing 14. Moreover, it is possible to transmit sound from the speaker 17 toward the outside of the casing 14 via the first duct 31 as it is, and to guide sound from the speaker 17 into the closed space 21 via the second duct 32 to resonate mainly sound in the low frequency band within the closed space 21. As described above, since sound is transmitted toward the outside of the casing 14 by way of referent two paths, it is possible to produce deep sound to realize high sound quality.

Electronic apparatuses are not limited to the television 11, and the portable computers 41, 71 shown in the above-described embodiments, but may be also implemented as a matter of course to mobile telephones, and/or other electronic apparatuses like electronic book readers adapted for electronically displaying books and/or images, etc.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A television comprising:
a display comprising a screen configured to display an image;
a tuner configured to receive a broadcasting wave;
an electronic component separate from the display;
a casing comprising:
a first wall with an opening and configured to cover the electronic component from a direction;
a second wall with a second opening and configured to cover the electronic component from another direction; and
a third wall with a third opening over the first wall and the second wall;
a stand configured to support the casing;
a fan in the casing and configured to send air toward at least the third opening; and
a radiating member comprising regions facing the first opening, the second opening and the third opening, the radiating member positioned between the fan and the third wall, wherein
the second wall comprises a recessed part and a projection projected toward the outside of the casing; and
apart of the fan faces the recessed part from inside the casing.

2. The television according to claim 1, wherein:
the fan comprises a motor; and
at least a part of the motor is within the recessed part.

3. The television according to claim 1, further comprising
a projected part configured to space the fan and the second wall, the projected part provided along a periphery of the recessed part.

4. The television according to claim 1, further comprising
a member within the casing configured to partition a space comprising the fan, the radiating part and the electronic part.

5. The television according to claim 1, wherein:
the casing comprises a first case that is visually recognizable and a second case on the side opposite to the first case; and
the second wall is a part of the second case.

6. The television according to claim 1, wherein
the first opening and the second opening are at positions intersecting each other when viewed from a direction where the third wall extends.

7. A electronic apparatus comprising:
an electronic component;
a casing comprising:
a first wall with an opening and configured to cover the electronic component from a direction;
a second wall with a second opening and configured to cover the electronic component from another direction; and
a third wall with a third opening over the first wall and the second wall;
a fan with the casing and configured to send air toward at least the third opening: and
a radiating member comprising regions facing the first opening, the second opening and the third opening, and the radiating member between the fan and the third wall, wherein
the second wall comprises a recessed part and a projection projected toward the outside of the casing; and
apart of the fan faces the recessed part from inside the casing.

8. The electronic apparatus according to claim 7, wherein:
the fan comprises a motor; and
at least apart of the motor is within the recessed part.

9. An electronic apparatus according to claim 7, wherein
the first opening and the second opening are at positions intersecting with each other when viewed from a direction where the third wall extends.

10. The electronic apparatus according to claim 7, further comprising
a projected part configured to space the fan and the second wall, the projected part along a periphery of the recessed part.

11. An electronic apparatus comprising:
a component; and
a casing comprising:
a first wall with an opening and configured to cover the component from a direction;
a second wall with a second opening and configured to cover the component from another direction; and
a third wall over the first wall and the second wall; and
a fan in the casing and configured to send air toward at least the third wall, wherein
the second wall comprises a recessed part and a projection projected toward the outside of the casing; and
a part of the fan faces the recessed part from inside the casing.

12. An electronic apparatus comprising:
a component;
a casing comprising a shape swollen from a bottom wall toward the outside;
a recessed part within the casing;
a fan in the casing, wherein
at least a part of the fan is configured to be inserted into the recessed part.
